(19) United States
(12) Patent Application Publication
(10) Pub. No.: US 2025/0141318 A1
(43) Pub. Date: May 1, 2025

(54) MOTOR WITH TWO OR MORE MAGNETIC SENSORS

(71) Applicant: Asetek Danmark A/S, Aalborg Øst (DK)

(72) Inventors: Allan Kaa JENSEN, Storvorde (DK); Jes LUNDBERG, Skørping (DK)

(21) Appl. No.: 18/927,398

(22) Filed: Oct. 25, 2024

(30) Foreign Application Priority Data
Oct. 26, 2023 (DK) PA202330293

(51) Int. Cl. H02K 11/215; G06F 1/20; H02P 6/16; H05K 7/20

(52) U.S. Cl. CPC H02K 11/215; G06F 1/20; H02P 6/16; H05K 7/20272; H02K 2211/03

(57) ABSTRACT

A brushless motor having a rotor arranged to rotate around a rotor axis and a stator. The rotor comprising a plurality of magnetic poles comprising at least a first magnetic pole, and a second magnetic pole. The motor further has a first magnetic sensor and a second magnetic sensor, where the first magnetic sensor and the second magnetic sensor are arranged statically relative to the stator. The first magnetic pole is arranged at a first angle and the second magnetic pole is arranged at a second angle while the first magnetic sensor and the second magnetic sensor are arranged with an angle difference corresponding to the angle difference between the first angle and the second angle. The first magnetic sensor and the second magnetic sensor are configured to combine the signals output by the first magnetic sensor and the second magnetic sensor such that the combined signal being used for the control of the brushless motor.

### FIELD OF THE DISCLOSURE

The present disclosure relates to the field of cooling of computer units and liquid pumps for performing this cooling. More specifically, aspects of this disclosure relate to a cooling system with magnetic sensors.

### BACKGROUND OF THE DISCLOSURE

The present disclosure relates to electrical motors and motor control using magnetic sensors. In the art electrical motors are used extensively and many products contain electrical motors. Electrical motors are used in various fields such as manufacturing, help with manual labor, in transportation and so on.

Brushless motors have become popular as they are more resistant to wear than motors having brushes. Furthermore, brushless motors are more resistant to harsh environments, e.g., a wet environment.

Magnetic sensors are used in the art to detect the position of magnetic poles of rotor magnets. The magnets of the rotor yield a magnetic field which depends on how the rotor is positioned. The magnetic field is measured by the magnetic sensors. For a brushless motor to run the magnets of the rotor need to be rotated by a force. This force is provided by running current through wires acting as electromagnets. The electromagnets can be controlled such that the rotor will continuously be subjected to a force to maintain rotation by turning off and on the electromagnets at specific times. Control of a motor can be carried out based on the position information collected by the magnetic sensors of the motor supplying knowledge of when to apply voltages to which windings of the motor to facilitate the desired rotation to run or stop the motor.

It is known in the art to use multiple magnetic sensors in order to control the rotation direction of the motor as this cannot be determined by a single magnetic sensor. Solutions with multiple magnetic sensors use the magnetic sensors to determine the rotation direction of the rotor.

Examples of using magnetic sensors for controlling motors are disclosed in DE10334204A1 and CN202076916U, which are incorporated in the present disclosure by reference.

Different problems arise when an electrical motor is to be used in a liquid cooling pump, when the rotor of the motor may be immersed in a cooling liquid like, e.g., water or oil. Due to the immersion of the rotors, it is not possible to place a magnetic sensor very close to the magnetic poles of the rotor. Distant placement of magnetic sensors results in a weaker signal detected by the magnetic sensor from the magnetic field. When the signal is weaker the motor is more difficult to control as the position of the rotor is more uncertain and the control unit will be less accurate regarding when to apply voltage in the windings of the stator. If the signal from the magnetic sensor is too low the motor may even stop working or fail to start as it does not know how the rotor is positioned.

Other problems with magnetic sensors in a motor may also arise, e.g., if a motor is placed close to a magnet which creates a background magnetic field and thereby affects the magnetic field at the position of the magnetic sensor of the motor. The background magnetic field may give an off-set error to the motor which may cause the motor to have reduced efficiency or otherwise malfunction.

Attempts have been made to solve these problems by using multipole magnets in brushless motors. One of the problems with multipole ring magnets is that the pole strengths vary from pole to pole. The total pole strength of all the south poles is equal to the total pole strength of all the north poles, but the individual poles may vary in magnetic strength. The sensor may not sense all of the poles if one of the poles produces a magnetic field that is too weak to be detected by the sensor. Using inputs from a magnetic sensor resulting from a multipole magnet with varying pole strength for controlling a motor may lead the motor to malfunction, e.g., by the motor running at too few rotations per minute, by the motor having an uneven duty circle, by the motor stopping and restarting too often, and/or by the motor being unable to start.

For at least the above-described reasons, a system for improving the motor design and the control of the motor is needed.

### SUMMARY OF THE DISCLOSURE

A first aspect of the present disclosure is:

A brushless motor comprising:
a rotor comprising a plurality of magnetic poles, the plurality of magnetic poles comprising at least a first magnetic pole and a second magnetic pole, wherein the rotor is arranged to rotate around a rotor axis;
a stator;
a first magnetic sensor;
a second magnetic sensor;
wherein the first magnetic sensor and the second magnetic sensor are arranged statically relative to the stator;
wherein the first magnetic pole is arranged at a first angle and the second magnetic pole is arranged at a second angle, wherein an angle is defined as an angle around the rotor axis of the rotor in a plane normal to the rotor axis;
wherein the first magnetic sensor and the second magnetic sensor are arranged with an angle difference corresponding to the angle difference between the first angle and the second angle;
wherein the first magnetic sensor and the second magnetic sensor are configured to combine signals output by the first magnetic sensor and the second magnetic sensor to form a combined signal, wherein the combined signal is used for control of the brushless motor; and
wherein the rotor and the stator rotate relative to each other.

Based on the first magnetic sensor and the second magnetic sensor being configured to combine signals, it is understood that they may be electrically connected in such a way that the signals are combined. For analogue sensors, this may be a direct electrical combination of the analogue output. For digital sensors, the combination may be via gates that allow the mathematical combination of the signals, such as addition, subtraction, and/or averaging of the signals.

In a variant of the first aspect, the brushless motor comprises:
a rotor comprising a plurality of magnetic poles, the plurality of magnetic poles comprising at least a first magnetic pole and a second magnetic pole, wherein the rotor is arranged to rotate around a rotor axis,
a stator,
a first magnetic sensor,
a second magnetic sensor,
the first magnetic sensor and the second magnetic sensor being arranged statically relative to the stator,
the first magnetic pole being arranged at a first angle and the second magnetic pole being arranged at a second angle where an angle is defined as an angle around the rotor axis of the rotor in a plane normal to the rotor axis,
the first magnetic sensor and the second magnetic sensor being arranged with an angle difference corresponding to the angle difference between the first angle and the second angle,
the rotor and stator being able to rotate relative to each other.

In a preferred embodiment, the brushless motor is adapted for driving a liquid pump. A liquid pump needs to operate in specific conditions, i.e., being at least partially submerged in the liquid to be driven by the pump, which puts limitations on the design. Such limitations include the dimensions of the pump, which needs to be compact and must have spacing which accounts for liquids being less compressible than gas therefore requiring more clearance than pumps operating with gas. This imposes several limitations on the placement of components such as sensors.

By the rotor comprising a plurality of magnetic poles is understood that the rotor may be magnetized, that one or more magnets may be attached to said rotor and/or be at least partially embedded in said rotor.

By the first magnetic sensor and the second magnetic sensor being arranged statically relative to the stator is understood that the motor is assembled such that the first and second magnetic sensors do not move relative to the stator during operation of the motor. This arrangement of the first and second magnetic sensors results in the rotor and thereby the plurality of magnetic poles moving relative to the first and second magnetic sensors during operation of the motor, thereby subjecting the first and second magnetic sensors to a varying magnetic field. In some variants the two or more magnetic sensors of the brushless motor may be attached to or at least partially embedded in the housing of the stator.

By the first magnetic sensor and the second magnetic sensor being arranged at a first angle and a second angle, respectively, is understood that they are located at different angular positions of a spherical coordinate system having the rotor axis as in the plane of rotation of the rotor at the center.

By the first magnetic sensor and the second magnetic sensor being arranged with an angle difference corresponding to the angle difference between the first angle and the second angle is understood that the first magnetic sensor and the second magnetic sensor are arranged with the same angle difference as the first magnetic pole and the second magnetic pole, whereby there is a rotational position of the rotor for which the first magnetic pole is aligned with the first magnetic sensor while the second magnetic pole is simultaneously aligned with the second magnetic sensor or that there is a rotational position of the rotor for which the first magnetic pole is aligned with the second magnetic sensor while the second magnetic pole is simultaneously aligned with the first magnetic sensor.

It is to be understood that the in preferred variants the plurality of magnetic poles are comprised in a single magnet. The first magnetic sensor and second magnetic sensor, as well as any potential additional sensors, are chosen and arranged relative to each other. Hence, the first magnetic sensor and the second magnetic sensor are arranged such that the angle difference corresponds to an integer multiple of the angle difference between neighbouring magnetic poles in the plurality of magnetic poles of the magnet. In a preferred variant the integer multiple is one, such that the first magnetic sensor and the second magnetic sensor are arranged to simultaneously detect a first magnetic pole and a second magnetic pole being neighbours.

In context of this application a magnetic pole of the plurality of magnetic poles is considered aligned with a magnetic sensor when that magnetic pole is in the rotational position where the magnetic field from that magnetic pole affects the sensor the most out of all possible rotational positions of that magnetic pole. For a magnet on a rotor capable of rotating and a magnetic sensor fixed relative to the stator the magnetic pole and the magnetic sensor may be aligned when the magnetic pole and the magnetic sensor are arranged at the same angle in a plane normal to the rotor axis. The sensor and the magnet do not need to be arranged in the same plane normal to the rotor axis. Alignment of a magnetic sensor and a magnetic pole occurs during a full rotation of the rotor when the magnetic pole is closest to the magnetic sensor, this may for multiple magnetic poles or sensors happen more than once for a full rotation of the rotor. Thus, aligning a magnetic pole and a magnetic sensor is not about placing the magnetic pole and the magnetic sensor as close to each other as possible in the design of the motor.

Having the brushless motor include both a first magnetic sensor and a second magnetic sensor provides multiple benefits. By having multiple magnetic sensors, the detected magnetic fields may be combined to minimize the effects of suboptimal components and/or placement due to the physical limitations of the physical system of the motor. Thus, having multiple sensors enables the sensors to be located further from the magnetic poles that are sources of the magnetic field which it is desired to detect, the magnetic sensors may even be located where they detect fringe fields where the magnetic fields may have nonlinear behaviours. Furthermore, such a configuration with two or more magnetic sensors allows reduction of the effect of variance of the magnetic poles of the motor. The magnetic poles of the motor may vary in strength and having two magnetic sensors measuring a magnetic pole each makes the system more robust for variations of the strength of the magnetic poles and therefore to compensate for time jitter of the sensed magnetic fields. In addition, the two or more magnetic sensors may be configured such that they can at least partially remove the unwanted effects of a uniform background magnetic field, which would otherwise obscure the desired measurements. Such a background magnetic field may for example occur due to the electronics of the brushless motor which causes the stator to be the source of magnetic flux in addition to the magnetic field originating from the plurality of magnetic poles of the rotor. A background magnetic field may arise from other electric or magnetic elements placed around the brushless motor and/or from electrical parts of the brushless motor.

In a preferred variant the first magnetic sensor and the second magnetic sensor are arranged such that they are exposed to the magnetic field from the first magnetic pole and the second magnetic pole when the corresponding magnetic poles are aligned with the magnetic sensors.

In some variants the first magnetic sensor and the second magnetic sensor may be arranged with different radial positions relative to the rotor axis of the rotor.

In a preferred variant, the brushless motor is comprised in a liquid pump, the brushless motor further comprising a seal and the rotor being arranged such that it is at least partially immersed when the motor is pumping liquid.

According to a further embodiment of the first aspect of the disclosure, the magnetic poles are evenly distributed angularly around the rotor axis.

Even distribution of the magnetic poles of the plurality of magnetic poles angularly around the rotor axis enables straight forward determination of the position of a magnetic pole based on the measurement of the first and second magnetic sensors. However, it is to be understood that due to production limitations and imperfections of the magnets and magnetic poles some variations may occur such that the magnetic field of the plurality of magnetic poles exhibit nonlinearities.

According to a further embodiment of the first aspect of the disclosure, wherein the first and second magnetic poles are of opposite magnetization.

Having a first and second magnetic pole of opposite magnetization means that the combination of the signals detected from the magnetic fields arising from the first magnetic pole and the second magnetic pole may be of equal sign and thus an average of the magnetic field from the two magnetic poles may be obtained. For a configuration that can obtain the average of the magnetic field from two magnetic poles having opposite magnetization a background uniform magnetic field will have no effect on the detection of the two magnetic poles as the part of the signals from the background field will cancel out when the average of the two signals are obtained.

According to a further embodiment of the first aspect of the disclosure, the first magnetic pole and the second magnetic pole are poles of a ring magnet, the ring magnet being diametrically magnetized.

A ring magnet may beneficially be arranged with the ring-shaped rotor of a brushless motor. In a preferred variant the ring magnet is mounted substantially concentrically with the rotor of the brushless motor. In a preferred variant the ring magnet may be dimensioned similarly to the rotor, e.g., by having an inner radius being the same and the outer radius of the rotor or having an outer radius being the same as the inner radius of the rotor.

Diametrical magnetization of the ring magnet is well suited for the distribution of magnetic poles with opposing magnetization radially around the rotor axis thereby providing the first magnetic sensor and the second magnetic sensor with a periodically varying magnetic field when the ring magnet rotates with the rotor of the brushless motor.

According to a further embodiment of the first aspect of the disclosure, the first magnetic sensor and the second magnetic sensor are analogue magnetic sensors.

By using analogue magnetic sensors, it is possible to directly combine the output signals detected by the two or more magnetic sensors thereby obtaining the benefits of combined magnetic signals while reducing or eliminating the need for postprocessing of the detected magnetic signals. The use of analogue magnetic sensors simplifies the detection system.

According to a preferred variant of the first aspect of the disclosure, the magnetic sensors are Hall effect sensors.

Using Hall effect sensors provides a cheap and precise brushless motor.

According to a preferred variant of the first aspect of the disclosure, the axes of both magnetic Hall sensors are parallel, and the Hall effect sensors measure the magnetic field along the parallel axes.

By the axes being parallel the combination of the filed is simplified as a specific magnetic pole will subject each of the magnetic sensors with a similar field when aligned with that particular magnetic sensor.

In a preferred variant the measurement axes of the first magnetic sensor and the second magnetic sensor will be parallel with each other and with the rotation axis of the rotor.

According to a further embodiment of the first aspect of the disclosure the brushless motor further comprises a control unit comprising a processor, and the magnetic sensors are electrically coupled to the control unit in such a configuration that a signal from a uniform magnetic field cancels out.

By a signal from a uniform magnetic field cancelling out is understood that the signal detected by the first magnetic sensor and the filed detected by the second magnetic sensor will be of the same magnitude and that they will be combined in such a manner that they oppose each other. As will be discussed in more detail in the examples below such coupling may be achieved in multiple ways. One option is that the detected signals will be of same magnitude and opposite sign such that they will cancel each other. Another option is that they will be of the same sign but combined in such a manner that in the combination they will be of opposite sign and counteract each other.

Such an electrical configuration has the benefit of allowing the varying magnetic signal arising from the plurality of magnetic poles rotating with the rotor of the brushless motor to be separated from an external uniform magnetic field, thereby decreasing the noise and/or shift of the signal and improving the quality of the detected signal necessary for the control of the brushless motor.

According to a preferred variant of the first aspect of the disclosure, the measuring axis of the first sensor is opposite the direction of the measuring axis of the second sensor.

The measuring axis of the first sensor being opposite the direction of the measuring axis of the second sensor may also be described as the first and the second sensor having opposite polarization. When the sensors are of opposite polarization a magnetic field with the same directionality will be registered as a positive field by one sensor and as negative by the other sensor having the opposite polarization.

Such a configuration of opposite direction of the measurement axes is a way obtaining sensed magnetic signals that may cancel each other out when the electrical signals originating from the first magnetic sensor and the second magnetic sensor are combined.

According to a preferred variant of the first aspect of the disclosure, the first and second magnetic sensors are positioned with an angle difference corresponding to the angle between two neighboring magnetic poles.

By having the first and second magnetic sensor arranged with an angel difference corresponding to the angle difference between two neighboring magnetic poles it is ensured that the two magnetic sensors are placed as close to each other as possible while still being able to compensate for variations of the magnetic fields from the magnetic poles. Such an arrangement provides the best reduction effects from magnetic background fields that is not perfectly uniform.

In a preferred variant the first and second magnetic sensors are positioned with an angle difference corresponding to the angle between two neighboring magnetic poles of a plurality of angularly evenly distributed magnetic poles having alternating magnetic pole orientation.

Having the first and second magnetic sensor arranged with an angel difference corresponding to the angle difference between two neighboring magnetic poles that belong to a magnet having magnetic poles distributed evenly with respect to angle around the rotor axis, periodic signals will be obtained throughout the entire rotation of the rotor and magnetic poles rotating along with the rotor, thereby providing a periodically repeating signal. As the ideal signal would be an identical repetition with the period of the evenly distributed magnetic poles of the plurality of magnetic poles any imperfections in the system will be detectable as the deviation from this ideal simplifying the correction for such imperfections of the actual system.

According to a further embodiment of the first aspect of the disclosure, the brushless motor being comprised in a liquid pump, the brushless motor further comprising a seal and the rotor being arranged such that it is at least partially immersed when the motor is pumping liquid.

According to a further variant of the first aspect of the disclosure, the first magnetic sensor and the second magnetic sensor are arranged in the same sensor plane, said sensor plane being parallel to the plane in which the first magnetic pole and the second magnetic pole are arranged.

In a preferred variant the first magnetic sensor and the second magnetic sensor are arranged radially between the rotor axis and the largest of the outer radius of the rotor or stator whichever is the largest.

Such an arrangement places the magnetic sensors to be placed above or below the plurality of magnetic poles, such that they are close enough to detect the periodically varying magnetic field during the rotation of the rotor while not being a hindrance to the movement of the rotor.

According to a further embodiment of the first aspect of the disclosure, the first magnetic sensor and the second magnetic sensor are arranged with substantially the same radial distance from the rotor axis as the center of each of the plurality of magnetic poles.

In a preferred variant the first magnetic sensor and the second magnetic sensor are located in the same sensor plane, the sensor plane being parallel to the plane of the plurality of magnetic poles and the first magnetic sensor and second magnetic sensor are arranged with substantially the same radial distance from the rotor axis as the center of each of the plurality of magnetic poles.

In this arrangement the first magnetic sensor and second magnetic sensor are placed directly above or below the center of the plurality of magnetic poles, i.e., with the same radial distance in a parallel plane, allowing them to be placed such that they will during the rotation of the magnetic poles with the rotation of the rotor when the brushless motor is active intermittently experience the same magnetic field from each pole. Such arrangement of the magnetic sensors leads to them detecting fringe fields of the magnetic poles, which in turn is made suitable for the purpose of providing a control signal for the brushless motor due to the combination of the signal from the first and second magnetic sensors.

A second aspect of the present disclosure is:

A method for controlling a brushless motor for driving a liquid pump comprising:
providing a magnet having at least a first magnetic pole and a second magnetic pole, wherein the magnet is arranged to rotate with a rotor of the brushless motor;
providing a first magnetic sensor recording a first signal;
providing a second magnetic sensor recording a second signal;
combining the first signal and the second signal to form a combined signal;
controlling the brushless motor according to the combined signal.

As previously described collecting a signal from at least two separate magnetic sensors and combining these signals it is possible to improve the data on which the control of the motor is based, e.g., by reducing noise, time jitter and/or by reducing the effect of a uniform external magnetic field. Combining the magnetic sensor data also improves the resulting dataset such that it is possible to use it for control of the brushless motor even if the placement of the first and second magnetic sensors is physically restricted such that only fringe fields and/or nonlinear magnetic fields may be sensed from the rotating plurality of magnetic poles. Hence, driving the brushless motor according to the combined signal from a first magnetic sensor and a second magnetic sensor improves the motor control of the brushless motor.

In a variant the method for controlling a brushless motor for driving a liquid pump comprising:
providing a brushless motor as described by the first aspect of the disclosure;
providing the first magnetic sensor recording a first signal;
providing the second magnetic sensor recording a second signal;
combining the first signal and the second signal;
controlling the brushless motor according to the combined signal.

In a preferred variant the brushless motor comprises a control unit with a processor in which the collected magnetic signals may combined and/or which directs the control of the brushless motor based on the combined signal of the first magnetic sensor and the second magnetic sensor.

According to a preferred variant of the second aspect of the disclosure the step of combining the first signal and the second signal comprises averaging the signals, whereby the impact of the variance of magnetic poles of the rotor on the control of the motor is decreased.

According to a preferred variant of the second aspect of the disclosure, the combining of the first magnetic signal and the second magnetic signal is in such a way that an influence of an external magnetic field is reduced.

Reduction of the magnetic field may be achieved by the previously described configurations. In preferred variants the signals are combined such that when averaging the signals a uniform external magnetic field will give rise to the same magnitude but differing sign from the two sensors, such that they cancel or at least reduce each other. By reducing the effect of the external magnetic field, the signal from the magnetic poles necessary for control of the brushless motor is more clearly detected. Shifts from changes in an external magnetic field will be minimized and the risk of misinterpreting the detected fields from the magnetic poles will be decreased.

According to a further embodiment of the second aspect of the disclosure, the external magnetic field is reduced by the first magnetic sensor recording the magnetic field in an opposite direction of the second magnetic sensor, such that averaging the first signal and the second signal reduces the influence of a static magnetic field.

In such a configuration the sensors are of opposite polarity, such that a uniform magnetic field will affect each sensor by the same magnitude but with opposite sign, such that when the detected signals are combined, they will cancel each other out.

According to a further embodiment of the second aspect of the disclosure, the external magnetic field is reduced by the first magnetic sensor recording the magnetic field in the same direction and the combination is such that the signal of the first sensor is of opposite sign of the signal of the second sensor.

In such a configuration the sensors are of the same polarity such that they will detect a uniform magnetic field as having the same magnitude and same sign. By combining the signals such that one of the is reversed compared to the other, e.g., by changing the electrical wiring to be opposite the standard configuration, the sign of one signal is reversed during the combination of the signals, whereby is achieved a resulting output where the effect of the uniform magnetic field is reduced while the signal from the magnetic poles remains.

According to a further embodiment of the second aspect of the disclosure, the first magnetic sensor and the second magnetic sensor record nonlinear magnetic fields from the magnet of the rotor and/or form the currents of the stator such that the combination of the recorded first signal and second signal compensates for the nonlinearity.

In particular, when the brushless motor is used for driving a liquid pump, there are restrictions of how the components such as the sensors can be arranged due to physical spacing and the presence of liquid, e.g. there must be additional spacing between the rotor and the stator when driving a liquid with increased resistance compared to a gas pump. Due to such placement restrictions, it may be necessary to increase the distance between the magnetic sensors and the magnetic poles and/or to arrange the magnetic sensors at a location where the magnetic fields from the magnetic poles are not linear. For example, the sensors may be arranged such that they are attached to stator housing in a position above or below the plurality of magnetic poles, i.e. shifted to a different plane along the rotor axis rather than or in addition to being spaced apart from the plurality of magnetic poles radially relative to the rotor axis.

When the magnetic sensors are arranged such that they will detect fringe fields of the magnetic poles, e.g., where they exhibit nonlinearities, the detected fields may be subject to noise, time jitter and/or shifts. By recording the fields using multiple magnetic sensors, such as a first magnetic sensor and a second magnetic sensor, it is possible to combine the recorded fields, e.g., by averaging the sensed fields, and by such combination minimizing adverse effect from the nonlinearity of the magnetic fields from the plurality of magnetic poles at the location of the magnetic sensors, thereby improving the control of the brushless motor based on the combined detected signal.

A third aspect of the disclosure is:

A liquid pump comprising a brushless motor, the brushless motor comprising:
a rotor comprising a plurality of magnetic poles, the plurality of magnetic poles comprising at least a first magnetic pole, and a second magnetic pole, wherein the rotor being arranged to rotate around a rotor axis,
a stator,
a first magnetic sensor,
a second magnetic sensor,
wherein the first magnetic sensor and the second magnetic sensor being arranged statically relative to the stator,
wherein the first magnetic pole being arranged at a first angle and the second magnetic pole being arranged at a second angle, wherein an angle is defined as an angle around the rotor axis of the rotor in a plane normal to the rotor axis,
wherein the first magnetic sensor and the second magnetic sensor being arranged with an angle difference corresponding to the angle difference between the first angle and the second angle,
wherein the first magnetic sensor and the second magnetic sensor being configured to combine the signals output by the first magnetic sensor and the second magnetic sensor to form a combined signal, wherein the combined signal being used for the control of the brushless motor, and
wherein the rotor and the stator being able to rotate relative to each other.

In an embodiment, the brushless motor is part of a cooling system for cooling a computer system. The cooling system comprise a liquid pump and may comprise a cold plate and a radiator. The liquid pump comprises the brushless motor for driving a flow of liquid. This is a standard setup for a cooling system for computers, The radiator is used to transport heat from the cooling liquid to the air such that the cooling liquid can be recirculated through the cold plate. In the cold plate heat from the computing device or devices is transported to the cooling liquid in order to cool the computing device or devices. In this way the heat of the computing devices is dissipated. The brushless motor may be used to circulate the cooling liquid inside the cooling system and thus cooling one or more computing units. The cooling system may be used to cool a CPU or a GPU.

A cold plate is normally arranged in contact with a processing unit such that heat can be transferred from the processing unit to the cold plate and further to the cooling liquid potentially running through the cold plate.

A radiator is used to cool cooling liquid by transferring heat from the cooling liquid to the surrounding air. This normally includes one or more fans to get a flow of cooling air to pass the fins of the radiator.

A liquid pump is used to circulate a flow of cooling liquid through the cold plate and the radiator such that heat is removed from the cold plate and transferred to the surroundings of the radiator mostly the air passing the radiator.

In an embodiment, a computer cooling system comprises the brushless motor described in previous embodiments of the first aspect of the disclosure. The computer cooling system is for cooling one or more computing units which may be of a server system or a single computer system. The computing cooling system may be used to cool a CPU or a GPU. The computer cooling system may comprise a liquid pump, a cold plate and a radiator, wherein the liquid pump comprises the brushless motor.

A fourth aspect of the disclosure is:

A cooling system for cooling a computer system, the cooling system comprising a brushless motor, the brushless motor comprising:
a rotor comprising a plurality of magnetic poles, the plurality of magnetic poles comprising at least a first magnetic pole, and a second magnetic pole, wherein the rotor being arranged to rotate around a rotor axis,
a stator,
a first magnetic sensor,
a second magnetic sensor,
wherein the first magnetic sensor and the second magnetic sensor being arranged statically relative to the stator,
wherein the first magnetic pole being arranged at a first angle and the second magnetic pole being arranged at a second angle, wherein an angle is defined as an angle around the rotor axis of the rotor in a plane normal to the rotor axis,
wherein the first magnetic sensor and the second magnetic sensor being arranged with an angle difference corresponding to the angle difference between the first angle and the second angle,
wherein the first magnetic sensor and the second magnetic sensor being configured to combine the signals output by the first magnetic sensor and the second magnetic sensor to form a combined signal, wherein the combined signal being used for the control of the brushless motor, and
wherein the rotor and the stator being able to rotate relative to each other.

In embodiments, the cooling system comprises a radiator.

In embodiments, the cooling system comprises a cold plate.

In embodiments, the cooling system comprises a liquid pump, wherein the liquid pump comprises the brushless motor. Thereby cooling liquid can be driven around in the cooling system with a continuously high pressure and heat can be dissipated effectively.

A fifth aspect of the disclosure is:

A computer cooling system comprising a brushless motor, the brushless motor comprising:
a rotor comprising a plurality of magnetic poles, the plurality of magnetic poles comprising at least a first magnetic pole, and a second magnetic pole, wherein the rotor being arranged to rotate around a rotor axis,
a stator,
a first magnetic sensor,
a second magnetic sensor,
wherein the first magnetic sensor and the second magnetic sensor being arranged statically relative to the stator,
wherein the first magnetic pole being arranged at a first angle and the second magnetic pole being arranged at a second angle, wherein an angle is defined as an angle around the rotor axis of the rotor in a plane normal to the rotor axis,
wherein the first magnetic sensor and the second magnetic sensor being arranged with an angle difference corresponding to the angle difference between the first angle and the second angle,
wherein the first magnetic sensor and the second magnetic sensor being configured to combine the signals output by the first magnetic sensor and the second magnetic sensor to form a combined signal, wherein the combined signal being used for the control of the brushless motor, and
wherein the rotor and the stator being able to rotate relative to each other.

In embodiments, the computer cooling system comprises a radiator.

In embodiments, the computing cooling system comprises a cold plate.

In embodiments, the computing cooling system comprises a liquid pump, wherein the liquid pump comprises the brushless motor. Thereby cooling liquid can be driven around in the computer cooling system with a continuously high pressure.

A sixth aspect of the disclosure is:

A method for controlling a liquid pump for cooling a computing unit, the method comprising the steps of:
providing a brushless motor, the brushless motor comprising a magnet having at least a first magnetic pole and a second magnetic pole, wherein said magnet being arranged to rotate with the rotor of the brushless motor;
providing a first magnetic sensor recording a first signal;
providing a second magnetic sensor recording a second signal;
combining the first signal and the second signal to form a combined signal; and
controlling the liquid pump according to the combined signal.

In embodiments, the method further comprise the step of pumping cooling liquid through a cold plate and a radiator, wherein the cooling liquid is driven by the liquid pump.

A seventh aspect of the disclosure is:

A method for controlling a cooling system comprising a liquid pump for cooling a computing unit, the method comprising the steps of:
providing a cold plate and a radiator,
providing a liquid pump comprising a brushless motor, the brushless motor comprising a magnet having at least a first magnetic pole and a second magnetic pole, wherein said magnet being arranged to rotate with the rotor of the brushless motor;
providing a first magnetic sensor recording a first signal;
providing a second magnetic sensor recording a second signal;
combining the first signal and the second signal to form a combined signal; and
controlling the cooling system according to the combined signal.

In embodiments, the method further comprises the step of pumping cooling liquid through the cold plate and the radiator, wherein the cooling liquid is driven by the liquid pump.

By having such methods one or more processing units of a computing device may be cooled and thus kept at a safe running temperature and this is ensure by a more stable pump and motor for a constant flow of liquid circulating in the system.

In the following specific examples according to aspects of the present disclosure will be explained in more detail with reference to the accompanying drawings. The present disclosure may, however, be embodied in different forms than depicted below, and should not be construed as limited to any examples set forth herein. Rather, any examples are provided so that the disclosure will be thorough and complete, and will fully convey the scope of the disclosure to those skilled in the art. Like reference numerals refer to like elements throughout. Like elements will, thus, not be described in detail with respect to the description of each figure.

### SUMMARY OF FIGURES

FIG. 1 illustrates a motor with two magnetic sensors.

FIG. 2 illustrates a motor with arc magnets.

FIG. 3 illustrates a motor with a diametrically magnetized ring magnet.

FIG. 4 illustrates two magnetic sensors in an external magnetic field.

FIG. 5 illustrates two magnetic sensors in a magnetic field from two magnets and an external magnetic field.

FIG. 6 illustrates an example signal from a magnetic sensor of a motor.

FIG. 7 illustrates a combined signal from two magnetic sensors in a motor.

FIG. 8 illustrates two magnetic sensors fastened on a PCB of a motor.

FIG. 9 schematically illustrates one configuration of the electronic connections between two Hall sensors and a motor driver/controller.

FIG. 10 illustrates an example signal from a single magnetic sensor in a motor with uneven strength of the magnetic poles.

FIG. 11 illustrates an example signal from two magnetic sensors in a motor with uneven strength of the magnetic poles.

FIG. 12 illustrates a liquid pump having two magnetic sensors.

### DETAILED DESCRIPTION OF THE DISCLOSURE

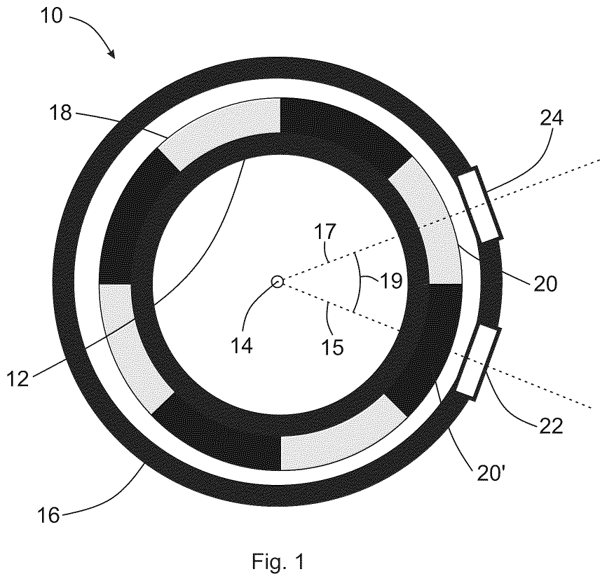

An example of an electromagnetic motor 10 is illustrated in FIG. 1. The part of the motor 10 that is stationary while the motor 10 is running is denoted the stator 16. The part of the motor 10 that is rotating while the motor 10 is running is denoted the rotor 12. An electromagnetic motor 10 has a stator 16 and a rotor 12. The rotor 12 and the stator 16 rotate relative to each other when the motor 10 is running. There may be one or more bearings (not shown in FIG. 1) used to connect the rotor 12 and the stator 16 to each other such that they can rotate in relation to each other. This is standard and used in many different variants of motors in the art.

According to this disclosure the electromagnetic motor 10 is a brushless motor. In a brushless motor 10 the rotor 12 comprises multiple magnetic poles, at least one south pole 20 and one north pole 20′ and the north and the south poles are of opposite magnetizations. A magnet will always have two magnetic poles of opposite magnetization. When describing magnetic poles, the poles is part of one or more magnets and thus no single magnetic pole is present. The magnetic poles may be comprised by one or more magnets or a single multipole magnet 18.

By a multipole magnet is meant a single magnet with more than two magnetic poles.

As illustrated in FIG. 1 the magnetic poles may be comprised in a ring magnet that is diametrically magnetized. In another embodiment the magnetic poles may be comprised in multiple arc magnets 18′ as illustrated in FIG. 2. The arc magnets 18′ may be placed in a circle around the rotor axis 14 of the rotor 12 where the direction of magnetization of the magnetic poles 20, 20′ facing away from the rotor axis 14 may alternate from neighbor to neighbor of the magnets as illustrated in FIG. 2. A first arc magnet is placed at a first angle 15 at which a first magnetic sensor 22 is also placed. A second arc magnet is placed at a second angle 17 at which a second magnetic sensor 24 is also placed. When having eight arc magnets as illustrated in FIG. 2, the angle difference 19 between the first angle 15 and the second angle 17 is 45°. The rotor may comprise any kind of magnets e.g., standard bar magnets or disc magnets.

In embodiments, a magnet of the rotor of the brushless motor comprises four or more magnetic poles. When a ring magnet with more than two poles are produced all the poles may not have the same size and magnetization strength. Normally the magnetic strength of each poles vary some percentages. Having two or more magnetic sensors may smooth this variation and provide a motor that runs more smoothly and e.g., activate the coils at adjusted timings compared to a perfect magnetization of the rotor magnet or magnets.

In a preferred embodiment the rotor 12 has a housing for holding the magnetic poles 20, 20′ in position in the motor 10 and a shaft that can be connected to a desired object to drive. The rotor 12 may have a core that responds to a magnetic field such as an iron core or similar. The rotor 12 is rotating around the rotor axis 14 of the rotor 12 also denoted the rotor axis 14.

In all embodiment of the disclosure the motor 10 comprises two or more magnetic sensors 22, 24. In some embodiments the motor 10 may comprise additional magnetic sensors. The first magnetic sensor 22 and the second magnetic sensor 24 are positioned stationary relative to the stator. The first and second magnetic sensor may be fastened to the stator 16 at positions where each sensor can sense the magnetic field from the magnetic poles of the rotor 12. The sensors may be fastened to the housing of the stator 16 The magnetic sensors 22, 24 are placed such that when a first magnetic sensor 22 is aligned with a first magnetic pole 20′ the second magnetic sensor is simultaneously aligned with a second magnetic pole 20 as illustrated in FIGS. 1, 2 and 3. In an embodiment the first magnetic sensor 22 is aligned with a first magnetic pole and the second magnetic sensor is aligned with a second magnetic pole of opposite direction of magnetization compared to the first magnetic pole.

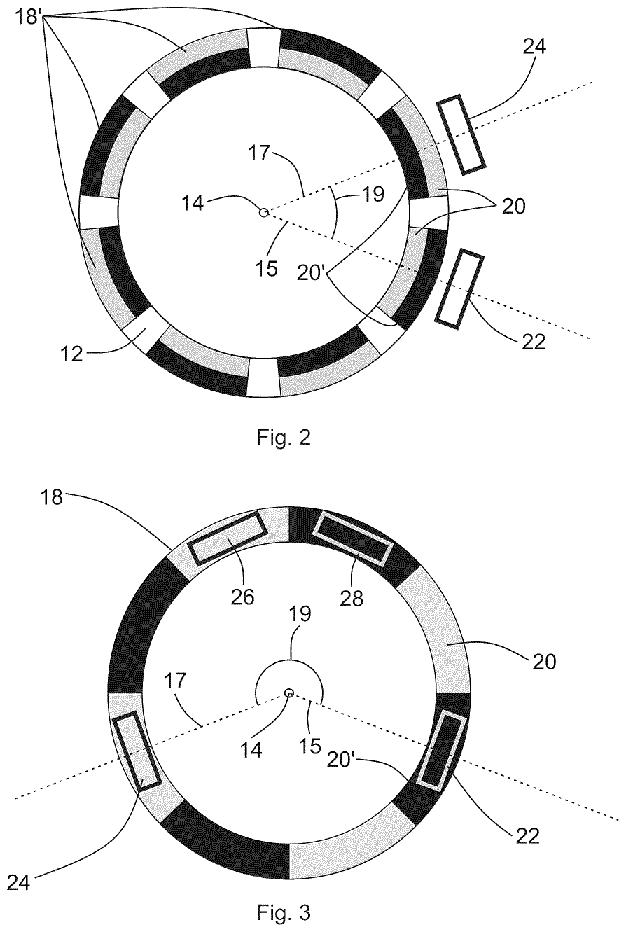

In some embodiments, an example of which is illustrated in FIG. 3, more than two sensors are used. In such embodiments the other sensors are simultaneously aligned with magnetic poles, these poles may have the same direction of magnetization as a pole with which the first or second magnet pole is aligned. An example of four magnetic sensors is shown in FIG. 3 where a first magnetic sensor 22 and a fourth magnetic sensor 28 are simultaneously aligned with magnetic poles 20′ being magnetized in the same direction while a second magnetic sensor 24 and a third magnetic sensor 26 are simultaneously aligned with magnetic poles 20 being magnetized in the opposite direction. The first magnetic sensor 22 is placed at a first angle 15. The second magnetic sensor is placed at a second angle 17. The angle difference 19 between the first angle 15 and the second angle 17 is for the case illustrated in FIG. 3 225°.

For embodiments of the system having two magnetic sensors, the two sensors may be placed either aligned with a magnetic pole pair with opposite magnetization or a magnetic pole pair with the same magnetization. These two configurations have different advantages which will be described later. If more than two sensors are used they may all be aligned with magnetic poles of the same magnetization, they may be arranged such that half of the sensors are aligned with poles of one magnetization and the other half is aligned with poles of opposite magnetization, or the magnetization of the poles aligned with the sensors may be mixed.

One way to achieve the alignment of two magnetic poles of opposite magnetization with two magnetic sensors at the same time is to distribute the magnetic poles evenly around the rotor axis 14 which will give a specific angle difference between each magnetic pole when using a polar coordinate system with the rotor axis 14 as the center point. The magnetic sensors are then placed with the same specific angle difference in between as the magnetic poles in the polar coordinate system. Thus, by this arrangement the two magnetic poles will have the maximum impact on the magnetic sensors simultaneously.

As illustrated in FIG. 1 this alignment of the magnetic sensors and the magnetic poles may be obtained by having a ring magnet with 8 poles resulting in a 45° angle difference between the center of each magnetic pole. A first magnetic pole 20′ is positioned at a first angle 15 in a polar coordinate system with the rotor axis 14 as the center. A second magnetic pole 20 is positioned at a second angle 17. The angle difference 19 between the first angle 20′ and the second angle 20 is for eight magnetic poles 45°, as illustrated in FIG. 1. The magnetic sensors are positioned with the same 45° angle difference, thus when the rotor 12 rotates and the next magnetic pole is aligned with the first magnetic sensor 22 a magnetic poles will also be aligned with the second magnetic sensor 24.

The first 22 and the second magnetic sensor 24 may align with any opposite magnetic pole pair. In FIG. 1 the multipole magnet 18 has eight magnetic poles spaced with an angle of 45°. For such a magnet the magnetic sensors may be placed with an angular difference of 45° or 135° or 225° or 315°. The rotor may comprise any even number of magnetic poles such as two, four, six, eight, ten, twelve, fourteen, sixteen, eighteen, twenty, twenty two, and so on. Thus, the corresponding angle difference between the magnetic poles depends on the number of magnetic poles.

The first and the second magnetic sensor may be positioned to align with two magnetic poles of any magnetization. If the magnetic poles are spaced with 45° in between as illustrated in FIG. 1. The spacing of the magnetic sensors may thereby be any multiple of 45°. The magnetic sensors do not need to be positioned to align with two adjacent magnetic poles but may be arranged at any distance which ensures that they align with poles simultaneously. In other embodiments with a different number of poles the described principle also applies simply with a different angle between the poles and the sensors being arranged with a multiple of this angle between them.

The stator 16 of the motor 10 comprises coils (not shown) made of loops of electrical conducting wire. The coils may be positioned in any appropriate configuration e.g., to obtain the strongest interaction between a magnetic field induced by a current flowing in the wire and the magnets on the rotor 12. There may be any number of coils preferably the same number of coils as the number of magnets of the rotor 12 when the rotor comprises multiple magnets like arc magnets. If the rotor comprises a single multipole magnet the number of coils preferably corresponds to the number of magnetic poles. The number of coils may be an unequal number of coils compared to the number of magnets in the rotor 12. The coils may be placed evenly on a circle around the rotor axis 14. The coils may overlap with each other.

In some embodiments the coils may be distributed non-evenly around the rotor axis 14. Such a configuration may e.g., be due to limited space for the arrangement of coils on one side of the stator 16.

The stator may comprise cores of each coil made of metal. The metal cores may be iron or another magnetic material. Iron cores can focus the magnetic field created by current of the coils towards the magnets of the rotor. This increases the efficiency of the motor. The metal cores may be arranged with a small angle away from a line going in the radial direction in the plane normal to the rotor axis where the center point is the rotor axis. This angle may be just the end of the metal core. This will affect the magnetic field created by the coils and the direction of the magnetic field will be redirected according to the small angle. This design of the metal cores results in a force when the coils are activated on the rotor in a specific direction. Thus, the rotor will move in this direction. Thus, when the motor starts the rotation direction of the rotor will always be the same. This results in a system that does not need magnetic sensors to measure which direction the rotor is rotating.

The brushless motor 10 may be of any type e.g., an out-runner motor or in-runner motor or a combination of the two. An outrunner motor is defined by having the rotor and the magnetic poles further away from the rotor axis 14 than at least the coils of the stator 16, such as further away from the rotor axis than the entirety of the stator 16. Thereby the rotor 12 is rotating on the outside of the stator 16. An in-runner motor is defined by having the magnets of the rotor 12 closer to the rotating axis 14 than at least the coils of the stator 16, such as closer to the rotor axis 14 than all of the stator.

The magnetic sensors may be either analogue or digital. Analogue magnetic sensors are preferred. The magnetic sensors may be of any appropriate type of sensor e.g., Hall effect sensors, magnetoresistors, variable reluctance sensors, fluxgate sensors, resonant sensors, induction magnetometer, linear variable differential transformer, Eddy current sensors, permanent magnet linear contactless displacement sensors, or similar. Hall effect sensors are preferred. The Hall effect sensors may be able to measure the magnetic field on one axis or multiple axes. A Hall sensor measuring the magnetic field strength on one axis can measure one component of the magnetic field and the component is determined by the orientation of the sensor and the magnetic field.

Using digital magnetic sensors in the brushless motor the digital magnetic sensor may provide either a digital output representing a value of the magnetic field strength, or the sensors may provide either a high or low value. Digital sensors providing a digital output representing a value of the magnetic field strength can provide the digital value to a processing unit which can do post processing on the signals from the two or more magnetic sensors e.g., calculate the average signal of the two or more signals. If the digital sensors provide a high or low value, the two or more signals may be added in time, but the average of the magnetic field at the position of the two sensors cannot be calculated.

The magnetic sensors may either be one axis magnetic sensors or multi-axis magnetic sensors. One axis magnetic sensors are sensors that measure the magnetic field along one axis. Multi-axis magnetic sensors are sensors that measure the magnetic field along multiple axes. Multi-axis magnetic sensor may measure the field along three orthogonal axes. Three one axis magnetic sensors may constitute a three-dimensional magnetic sensor. One axis magnetic sensors may be preferred as they are cheaper and/or simpler to implement.

As schematically illustrated in FIG. 9 the motor 10 may comprise a motor controller 46 having a processor, the motor controller 46 may also be denoted a motor driver. The motor controller 46 receives signals from the magnetic sensors 22, 24 and based on these signals controls the motor. The motor controller 46 may control the motor by adjusting when voltages are applied to the windings/coils of the stator 16 in order to drive the motor and make the rotor 12 rotate.

The two or more magnetic sensors 22, 24 are preferably arranged such that each sensor is simultaneously aligned with a magnetic pole. For the case with two magnetic sensors, a first magnetic sensor 22 and a second magnetic sensor 24, each sensor measure the magnitude of the magnetic field along the measurement axis of the sensor at the position of the sensor. This magnetic field may primarily be due to the magnet on the rotor 12. External magnetic fields from other sources may also be present depending on what surroundings the motor is placed in.

When placing the magnetic sensors other elements may take up the ideal position of the sensors. This may e.g., be the coils of the motor 10, housing, seals, screws, or other mechanical parts. If the motor 10 is for use in a liquid pump there may be a liquid tight seal between the rotor 12 and the stator 16 as the rotor 12 may be completely or partially immersed in liquid. Thus, mechanical constraints may cause the sensors to be distanced from the magnetic poles. The sensors may in an example be positioned in the same plane as the magnetic poles, that plane being normal to the rotor axis 14; such a configuration is illustrated in FIG. 1 and FIG. 2.

The brushless motor may have other features taking up the space around the magnetic poles such as metal cores and coils. Moreover the magnetic poles may be arranged such that the magnetic field is focused towards the coils of the stator. Thus, if the magnetic sensors cannot be placed in the same plane as the magnetic poles to obtain signals strong enough, the sensors may be place in off-set planes. In an example the sensors are positioned in an offset plane compared to the plane that includes all the magnetic poles. This is illustrated in FIG. 3 where the magnetic sensors are distributed with the same radial distance to the rotor axis 14 as the magnetic poles. Thereby the sensors have the shortest distance to the magnetic poles to produce the largest signal for controlling the motor 10 compared to being at other radial positions in the offset plane. In FIG. 3 a first magnetic sensor 22, a second magnetic sensor 24, a third magnetic sensor 26, and a fourth magnetic sensor are illustrated arranged in accordance with one embodiment of the disclosure. In an embodiment only two of the four illustrated magnetic sensors are comprised in the brushless motor.

The axis along which a magnetic sensor measures the magnitude of the magnetic field is denoted the measurement axis. Two axes being parallel may mean to be perfectly parallel or substantially parallel such as the maximum angle difference between the two axes is less than 25°, 20°, 15°, 10°, 5°, 4°, 3°, 2°, 1°, 0.5°, or 0,05°.

In general, the magnetic sensors can be arranged differently in many different setups, the setups defining how the measurement axes of the magnetic sensors are positioned. The setups do not describe how the magnetic sensors are electrically coupled. The setups can be divided into two groups of setups.

The first group of setups is defined by being arranged such that the measurement axes of the magnetic sensors are parallel.

The second group of setups is defined by being arranged such that the measurement axes of the magnetic sensors are not parallel. Thus, the second group includes a vast number of different setups.

For the first group of setups the first magnetic sensor 22 and the second magnetic sensor 24 have parallel measurement axes. One setup in the first group of setups is a setup having two magnetic sensors both being mounted in a similar fashion on a level surface resulting in the measurement axes being parallel. Another setup in the first group of setups has two magnetic sensors mounted on a level surface where one of the magnetic sensors is flipped upside down relative to the other magnetic sensor resulting in the measurement axes being parallel. Part of the signals from each sensor resulting from an external uniform magnetic field may be reduced to a non-significant magnitude in a combined signal either via the physical configuration of the sensors or via data processing. The configurations will be described more later.

In the second group of setups the measurement axes of the magnetic sensors are not parallel thereby complicating the removal of a background signal from the combination of signals collected by the two sensors. The influence of a signal from a uniform magnetic field will be reduced when the measurement axes of the sensors are not parallel e.g. when the measurement axes are arranged with an angle between them such as an angle of 45° or 30°, but in this case the effect of an external uniform magnetic field will not be completely removed.

Another way to reduce the effect of an external magnetic field is to use Hall sensors with three measurements axes. Using three Hall sensors with one axis can be identical to using one Hall sensor with three axes. The signal from each measurement axes of each of the two or more magnetic sensor may be combined to remove the effect of a uniform external magnetic field.

The two magnetic sensors may be coupled electrically together in various different configurations, the configurations do not depend on what setup the magnetic sensors have. The electrical coupling of the two or more magnetic sensors provides the possibility of combining the signals of the two or more sensors in such a way that the effect of magnetic pole strength variation and/or an external uniform magnetic field is removed or at least reduced.

In a group of configurations, the two or more magnetic sensors are electrically coupled together, meaning that at least one pin of each of the magnetic sensors are connected by a wire. The two magnetic sensors may be electrically coupled in parallel to combine the signals from each sensor. In one configuration, where the magnetic sensors are Hall sensors with two output pins and two supply pins, the signals of the two or more sensors are combined in parallel by connecting the specific pins of one Hall sensors with a corresponding pin of the other Hall sensor. Coupling two Hall sensors having two output pins and two supply pins in parallel means that the pins of the first Hall sensor are connected with the pins of the second Hall sensor. Thus, all the pins of one Hall sensors may be connected to a pin of the other Hall sensors. Each pin pair may be connected to a motor driver, or a processing unit used for controlling a motor. By coupling two Hall sensors in parallel the signal resulting from a magnetic field can be combined such that the average signal is transmitted to a motor driver, a motor controller, or a processor.

Another way to achieve a configuration where the two Hall sensors are connected in parallel is to connect the first and second supply pins of the first sensor with the corresponding first and second supply pin of the second sensor and couple the first output pin of the first sensor with the second output pin of the second sensor and couple the second output pin of the first sensor with the first output pin of the second sensor. Thus, swapping the connections to the two output pins of one of the Hall sensors as compared to the configuration described above. Each pin pair may be connected to a motor driver, or a processing unit used in the control for controlling a motor.

A third configuration for combining signals of Hall sensors having two output pins and two supply pins is to swap the two supply signals of one of the Hall sensors such that the first output pin, the second output pin, the first supply pin, and the second supply pin of the first sensor are connected respectively to the first output pin, the second output pin, the second supply pin, and the first supply pin of the second sensor. This configuration is illustrated in FIG. 9. Each of the two Hall sensors have two output pins 48A, 48C and two supply pins 48B, 48D. The first output pin 48A of the first and second magnetic sensors 22, 24 are connected in parallel to the motor controller 46 with electrical connections 42. The second output pin 48C of the first and the second magnetic sensor 22, 24 are likewise connected in parallel and to the motor controller 46. The first supply pin 48B of the first magnetic sensor 22 is connected in parallel to the second supply pin 48D of the second magnetic sensor 24. The first supply pin 48B of the second magnetic sensor 24 is connected in parallel to the second supply pin 48D of the first magnetic sensor 22. When the pins of the sensors are connected in parallel as described, the motor driver will receive a combined signal from the two Hall sensors that is the average of the two separate signals from the magnetic sensors.

Another way of processing the signals in both the first and second groups of setups is to have the signal from each magnetic sensor sent directly to the motor controller 46. The processor in the motor controller 46 may combine the two or more signals. Combining signals meaning using the signals in a calculation that may be adding the signals, averaging the signals, multiplying the signals and so on. The combination of the two or more signals depends on the orientation and position of the sensors and what signal they output. The processor may combine the signals from each sensor such that they do not cancel out the part of the signal due to the magnetic poles, instead the processor will calculate a signal where the parts of the signals that is due to the magnetic poles are added or averaged. One example is that two sensors are placed with the same orientation and aligned with two magnetic poles having opposite magnetization. The processor may multiply one of the signals with −1 before calculating the average of the signals as one of the sensors will measure a negative signal, meaning that it measures the magnetic field in the opposite direction than the direction of the magnetic field. Combining a positive and negative signal of almost the same magnitude may result in the two signals cancelling each other out.

In any of the setups processing of the signals like adding the signal or averaging the signals from the sensors may instead be performed using an operational amplifier, a digital processor or similar. Thereby there are multiple configurations of averaging or combining the signals from the two magnetic sensors. As described earlier the simplest one may be to couple the outputs of the two sensors in parallel as no extra elements are needed.

In any of the setups the two or more magnetic sensors may be configured to combine the signals of the magnetic sensors in such a way that the average signal of two poles aligned with the magnetic sensors is calculated. The magnetic poles may be configured such that the two magnetic poles are of opposite magnetization or equal magnetization. The setups may further be configured to reduce the effect of an external uniform magnetic field while still detecting the effect of the magnetic poles.

A system having two sensors arranged such that they align with a magnetic pole pair will be more resistant to pole strength variations compared to a system with only one sensor as two poles are used for in controlling the motor. As described above the sensors may be configured to compensate for magnetic pole strength variations and timing of the positioning of the magnetic poles also denoted jittering using various different configurations.

The motor 10 may have more than two magnetic sensors. These sensors may be placed in alignment with magnetic poles of the rotor 12. As described in different configurations a combined signal averaging the strength of the magnetic poles measured may be achieved, the number of poles yielding the combined signal correspond to the number of magnetic sensors in the rotor 12 if the sensors are aligned with the magnetic poles. The more sensors used to measure the magnetic poles of the rotor 12 the more precise a combined signal may be which provides a higher accuracy of timing in the control of the motor. Increasing the number of sensors will also increase the cost. The number of sensors that can be used to improve the signal is limited to the number of magnetic poles.

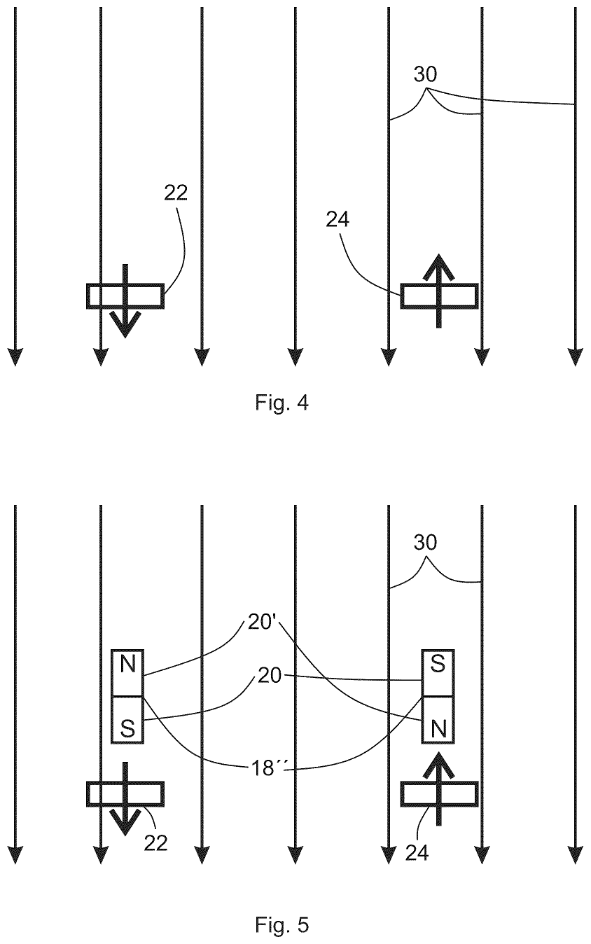

If a uniform or approximately uniform external magnetic field is present in the motor 10 this field may affect the measurements of the magnetic sensors in the motor 10. A uniform magnetic field 30 affecting two magnetic sensors is illustrated in FIG. 4. The uniform magnetic field 30 illustrated by arrows may be provided by an external element like a magnet or an electromagnet used in the surroundings of the motor. External magnetic fields from a magnet or an electromagnet are not perfectly uniform but may be approximated as a uniform magnetic field 30. The first magnetic sensor 22 and the second magnetic sensor 24 are positioned such that their measurement axes are parallel to the uniform magnetic field 30 but with opposite directions illustrated by the arrows on the sensors. An offset for each of the magnetic sensors is caused and combining the signals in one of the configurations described earlier will result in a combined signal without any offset. For the illustrated example, a combined signal becomes zero as the only magnetic field is a uniform magnetic field.

FIG. 5 illustrates a uniform magnetic field 30, two magnetic sensors 22, 24 placed with their measurement axes parallel to the uniform magnetic field, and a first magnet comprising a magnetic pole aligned with the first magnetic sensor and a second magnet comprising a magnetic pole aligned with the second magnetic sensor. The two magnets are illustrated as bar magnets 18″ but may be any type of magnet. The two magnetic poles aligned with the first and second magnetic sensors are of opposite magnetization. Adding the signal from the first magnetic sensor with the signal of the second magnetic sensor in such a way that the signal from the two aligned magnetic poles will add up results in a signal adding the effect of the magnetic field from the two aligned magnetic poles and remove the effect of the external uniform magnetic field 30. A uniform magnetic field may induce an offset in the measurements of each magnetic sensor. Thus, the measurements of each sensor may be too high or too low compared to the situation without the external magnetic field 30. When combining the signal from two magnetic sensors aligned with two magnetic poles of the same magnetization, an external field will cause an offset in the same direction for both of the sensors. By an offset in the same direction is meant an offset that is either positive for both sensors or negative for both sensors. Thus, the uniform magnetic field cannot be removed from the measurements without also removing the effect of the magnetic poles. The purpose of using a magnetic sensor in the motor 10 is to be able to detect the magnetic poles of the rotor 12, thus removing the effect of the magnetic poles would be detrimental to the working of the motor. The motor controller 46 needs to get information about the rotor 12 e.g. the rotor position in order to be able to control the voltages of the coils in the motor 10.

When combining the signals from two magnetic sensors that are aligned with a magnetic pole pair with opposite magnetization the offset due to the external magnetic field 30 from the first sensor 22 will cancel or reduce the offset from the second sensor 24. In this configuration the remaining part of the combined signal may mostly or only be due to the magnetic poles of the rotor 12. This is illustrated in FIG. 5. The sensors need to be coupled accordingly as described above. This combination where the background magnetic field is removed in a combined signal may be achieved by flipping one of the magnetic sensors upside down relative to the other sensor such that the direction on which the sensor measures is opposite of each other.

Thus, the system may remove part of an external magnetic field 30 when the magnetic sensors are arranged to align with a magnetic pole pair of opposite magnetization.

If adding a third sensor to make the system more robust to an external field. Combining the signal from three sensors will reduce or cancel the influence of an external field. Depending on how the signals from three sensors are coupled the effects of a background signal may not remove it completely when the external magnetic field is uniform. Three sensors may be used two at a time to cancel out uniform magnetic fields, and e.g., measure the strongest two of the three magnetic poles.

If four magnetic sensors are used, they may be positioned aligned with four magnetic poles. Two of the four magnetic poles may be of the same magnetization and the two others may be of an opposite magnetization. Using four magnetic sensors placed aligned with four magnetic poles provides a system capable of removing the effect of a uniform external magnetic field and averaging the signal from four magnetic poles. This may be done in a similar manner when adding additional sensors and therefore any number of sensors may be added.

The motor controller 46 of the motor may use the signals from the magnetic sensors to control the motor. It may be detecting the position of the rotor 12 by using the signals from the magnetic sensors. That may be by setting a threshold 32 for which a magnetic pole is detected. It may be by fitting a function to the signals or parts of the signals e.g., a sine or cosine function. It may be by comparing the signals to a calibration graph or some calibration data.

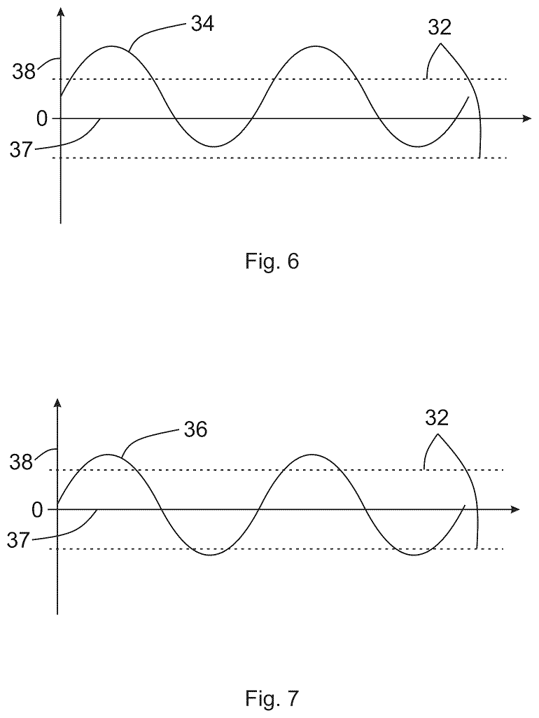

FIG. 6 illustrates a signal 34 from a magnetic sensor in a rotor 12 in the presence of an external magnetic field 30. The signal may be voltage of the sensor as a function of time, therefore the graph has a voltage axis 38 and time axis 37. The signal from the sensor may be in any appropriate unit, for Hall sensors voltage is normally used. FIG. 6 illustrates one example of how the signal 34 from a single magnetic sensor may be when the rotor 12 rotates. The sensor has two maxima and two minima corresponding to four magnetic poles having passed the magnetic sensor during the time interval shown. The motor controller may have a threshold 32 for when it will determine that a magnetic pole is aligned with the magnetic sensor. This threshold 32 corresponds to a specific voltage and is illustrated by a dashed line 32. The threshold 32 is both for positive voltages and negative voltages as this corresponds to a magnetic field with a certain magnitude but in opposite directions. The signal from the sensor is not centered around 0 voltage as there is an offset due to the external magnetic field 30. The external magnetic field 30 shift the signal in the illustrated example of FIG. 6 up in voltage. In other situations, the external magnetic field may e.g., shift the signal down in voltage if the external magnetic field 30 were in the opposite direction. The shift shown in the example of FIG. 6 is so large that the negative signal never exceeds the value of the threshold 32 and thus the motor 10 will never detect the type of magnetic poles associated with a negative signal of the magnetic sensor. This may cause the motor 10 to stop or malfunction e.g. if the motor needs to start but it cannot detect which magnetic pole is aligned with the magnetic sensor which in turn may cause the motor 10 to be unable to start at all.

FIG. 7 illustrates a combined signal 36 from two magnetic sensors when the rotor 12 rotates, an external field is present as in FIG. 6, and the magnetic sensors are aligned with two magnetic poles of opposite magnetization. The combined signal 36 from two magnetic sensors is shown as a function of time on a time axis 37 and a voltage axis 38. In the example of FIG. 7 the majority of the influence of the external field is cancelled out when the signals of the two magnetic sensors are combined as described earlier. If the external magnetic field 30 is uniform, the signal illustrated in the graph should be symmetrical around the axis of zero voltage as all of the part of the signal caused by the uniform external field would cancel out. If the external field is not completely uniform an offset may still be present in the combined signal, but the offset will be reduced compared to only having one magnetic sensor. In the example illustrated in FIG. 7 it is seen that both the positive and negative threshold 32 is reached and the motor controller 46 may therefore register the position of the rotor 12 of all the magnetic poles as they pass by the sensors.

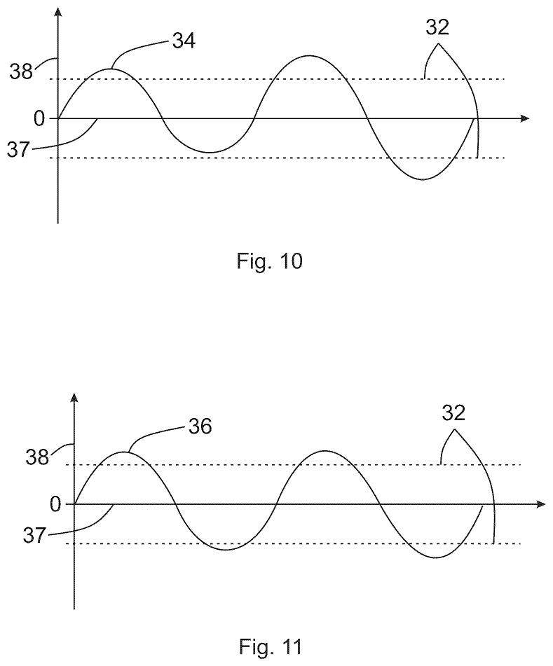

FIG. 10 illustrates how a signal 34 from a single magnetic sensor may look when the magnetic poles of the rotor 12 have different pole strengths. The different pole strengths results in varying amplitude of the signal 34 from the single magnetic sensor. These variations of the amplitude may lead to some magnetic poles not resulting in a signal higher than the threshold 32 and therefore not being registered as a magnetic pole. That is the case for the second magnetic pole in FIG. 10 not providing a strong enough negative signal to be below the negative threshold 32. The problem of varying strength of magnetic poles may be more important when the magnetic sensors cannot be placed close to the magnetic poles and therefore may produce a smaller signal. Having a low signal may also be due to the magnetic poles not being equally strong result in a signal from the magnetic poles being shifted in time and thus the sensor detects a wrong center of the magnetic poles and thus the motor starts to run less smooth having lower rotations per minute. The weak magnetic poles may even be weak enough to provide a magnetic field the sensors are not able to detect as a magnetic pole

Noise is always present when sensing signals, thus the part of the signal arising from the magnetic poles need to be higher than the noise. When collecting the signal using two sensors, the data processing may make the system more robust against noise and increasing the design freedom for the layout of the sensors of the motor as they may be placed further from the poles of the rotor 12 without the signal drowning in the noise.

FIG. 11 illustrates how a combined signal 36 from two magnetic sensors may look when the magnetic poles of the rotor 12 have different pole strengths, it illustrates the same variation in magnetic pole strength as the rotor 12 had in the example of FIG. 10. For two magnetic sensors the combined signal may reduce the effect of the variations in pole strengths on the combined signal. The pole strength variation effect may be reduced due to the that two magnetic poles are used measured in the combined signal and e.g., by averaging the signals from each sensor. By combining the signal of two sensors the resulting combined signal may have smaller variations and are thus more likely to allow the motor controller to determine when the magnetic sensors are aligned with a magnetic pole pair or not in order to more accurate timely detection of the magnetic poles and using that provides a more steady running velocity of the motor. It may be seen in FIG. 11 that all four peaks of the example signal exceed the threshold 32, whereas in the example signal of FIG. 10 collected by a single sensor one of the peaks was below the threshold 32 and might therefore not be detected.

In a preferred embodiment the brushless motor comprises a rotor comprising a first magnetic pole and a second magnetic pole. The rotor is arranged to rotate around a rotor axis. The brushless motor further comprises a first analogue magnetic sensor and a second analogue magnetic sensor. The first magnetic sensor is placed at a first angle 15 and the second magnetic sensor is arranged at a second angle 17 where angles are defined as an angle around the rotor axis of the rotor in a plane normal to the rotor axis. Thus, the angles are defined as the angle in a polar coordinate system with the rotor axis in the center and the plan of the coordinate system is normal to the rotor axis. The first magnetic pole and the second magnetic pole are arranged with an angle difference corresponding to the angle difference between the first angle 15 and the second angle 17. The rotor and the stator are arranged such that the rotor can rotate compared to the stator around the rotor axis. The stator housing may comprise bearings that provide the possibility of the rotor and stator to rotate relative to each other. The stator may be fixed, and the rotor be the element that is rotating. The first and the second magnetic sensor may be hall sensors capable of measuring the magnitude of a magnetic field along one measurement axis. The magnetic poles of the rotor may be comprised by a ring magnet that is diametrically magnetized. The ring magnet may be placed with the rotor axis as the center of the ring magnet such that the ring magnet rotates in a plane normal to the rotor axis. The ring magnet may have 8 magnetic poles such that there are approximately 45° between the center of each magnetic pole. The magnetic poles alternate magnetization along the circumference of the ring magnet such that there are 4 poles of a first magnetization and 4 poles of a second magnetization. The first angle 15 may be 0° and the second angle may be 45° hereby the angle difference between the two magnetic sensors is 45° which matches the angle difference between the center of two neighboring magnetic poles. This arrangement of the magnetic sensors and the magnetic poles ensures that when a first magnetic pole is aligned with a magnetic sensor, meaning the center of the magnetic pole is aligned with the first magnetic sensor, a second magnetic pole is further aligned with the second magnetic sensor. Thus, if one magnetic sensor is aligned with a magnetic pole the other magnetic sensor is also aligned with a magnetic pole and the two magnetic poles are of opposite magnetization. The two Hall sensors may be placed with the measurement axes being parallel with the rotor axis. The Hall sensors may further be arranged in a plane that is offset to the plane of the ring magnet. The Hall sensors may be arranged at the same radial distance to the center of the rotor axis as the magnetic poles of the rotor. The two Hall sensors may have two input pins and two output pins. The two Hall sensors may be connected to a motor driver by connecting the first output of the first sensor to the first output of the second sensor and to a signal pin of the motor driver. The second output of the first and second sensor may be connected to each other and a second signal pin of the motor driver. The first supply pin of the first sensor may be connected to a second supply pin of the second sensor and a pin of the motor driver. The second supply pin 48D of the first sensor 22 may be connected to the first supply pin 48B of the second sensor 24 and electrical ground. This electrical configuration results in the combination of the two signals originating from the two Hall sensors in such a manner that the output combined signal is the average of the two signals from the two Hall sensors. As two different supply pins of each sensor are connected as well as the two other supply pins, the effect of a uniform magnetic field will be cancelled out in the combined average signal. Moreover, two magnetic poles of opposite magnetization will affect a corresponding magnetic sensor simultaneously, the part of the signals arising from the magnetic poles will be averaged such that the combined signal will illustrate an average magnetic pole affecting a single magnetic sensor. The brushless motor may comprise a printed circuit board fastened on the stator and holding the magnetic Hall sensors. The brushless motor may be used in a liquid pump.

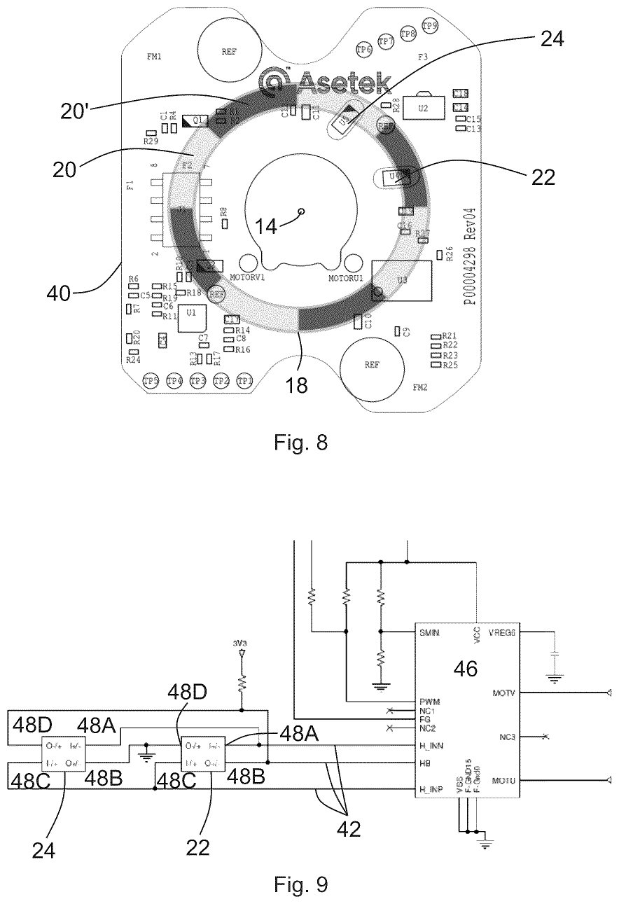

In all embodiments and as illustrated in FIG. 8 the motor may have a printed circuit board (PCB) 40 where the magnetic sensors may be attached. The PCB 40 may be placed in any appropriate position. The PCB 40 may be placed in a first plane normal to the rotor axis 14. The magnetic poles may be placed in a second plane normal to the rotor axis 14. The first and second plane may thereby be parallel and may be spaced apart by a distance. The distance may be as small as possible in order to bring the magnetic sensors on the PCB 40 as close to the magnetic poles as possible. FIG. 8 illustrates a PCB 40 placed above the plane of the magnetic poles when seen along the rotor axis 14. A motor 10 with a ring magnet having eight magnetic poles is illustrated. Thus, for the magnetic sensors to be aligned with a magnetic pole pair the angle between the sensors may be 45°. The sensor may further be placed at approximately the same distance from the rotor axis 14 as the magnetic poles. The sensor may further be placed at the same distance from the rotor axis 14 as the magnetic poles. In FIG. 8 the first magnetic sensor 22 is place at a first angle almost horizontally and the second magnetic sensor 24 is rotated 45° around the rotor axis 14 relative to the first magnetic sensor. The first and the second magnetic sensor is able to measure the magnetic field in at least one direction. The magnetic sensors may be able to measure the magnetic field in three directions. For the example where the sensors measure the magnetic field along one axis this axis may be parallel to the rotor axis 14. The magnetic sensors may be rotated around the measuring axis in any appropriate way as this should not affect the measurement of the magnetic poles. Therefore, the two sensors may be rotated compared to each other without disturbing the effect of using two sensors as long as the measurement axes are not changing/moving. The magnetic sensors may be arranged on the side of the PCB 40 that is facing the magnetic poles. The magnetic sensors may be arranged in a hole of the PCB 40 as illustrated in FIG. 8. The magnetic sensors may be arranged on the side of the PCB 40 facing away from the magnetic poles. The PCB 40 may be constructed such that the magnetic sensors may be replace if failing or an upgrade should be installed. The PCB 40 may also be constructed such that it can be replaced if malfunctioning or a new PCB 40 of the motor is to be installed. FIG. 8 illustrates an embodiment that provide a more accurate timely detection of the rotor and the magnetic poles and based on that timing the motor controller can control the motor to run more smoothly such as producing less noise having a more constant velocity and a rpm.

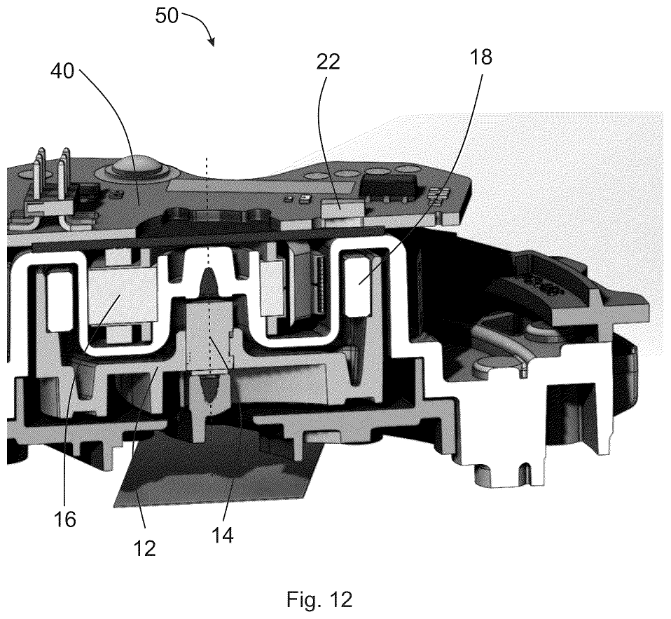

FIG. 12 illustrates a liquid pump 50 having a motor with two magnetic sensors. The illustrated motor is an out-runner motor. The rotor 12 of the motor may be partly or completely immersed in liquid of the liquid pump 50 as the rotor 12 may be arranged to move liquid and this may be by rotating a propeller or similar. The magnet of the illustrated exemplary motor is a ring magnet 18 with multiple poles and coils are placed on the inside of the multipole magnet 18. The stator 16 may comprise the coils for driving the motor. The stator may not be made for being in contact with liquid, thus the motor may comprise a liquid seal between the stator and the rotor such as a plastic layer. Having a plastic layer take up space inside the motor resulting in less space for magnetic sensors and a larger distance between the magnetic poles and the coils of the motor. The PCB 40 with the magnetic sensors 22, may be fastened to the stator 16. Only one of the two magnetic sensors are shown in FIG. 12. The magnetic sensors are arranged with the same distance to the rotor axis 14 as the magnetic poles but are displaced along the rotor axis 14. This arrangement of the sensors is the position where the strongest magnetic signal from the magnetic poles may be collected within the constraints of the structure where space is taken up by the rotor 12, the stator 16 or other parts of the pump. Therefore, the magnetic sensors may be placed at the edge of the ring magnet. At least for the reason that multiple magnetic poles and magnetic sensors may be used for controlling the motor and that the magnetic sensors may be placed with a substantial distance to the magnetic poles of a liquid pump the motor may be specially advantageously for liquid pumps.

Below is a list of reference signs used in the detailed description of the present disclosure and in the drawings referred to in the detailed description of the present disclosure.
10 motor
12 rotor
14 rotor axis
15 first angle
16 stator
17 second angle
18 multipole magnet
18′ arc magnet
18″ bar magnet
19 angle difference between the first angle 15 and the second angle 17
20 first magnetic pole
20′ second magnetic pole
22 first magnetic sensor
24 second magnetic sensor
26 third magnetic sensor
28 forth magnetic sensor
30 external magnetic field
32 threshold
34 signal from a single magnetic sensor
36 combined signal from two magnetic sensors
37 time axis
38 signal axis
40 Printed circuit board (PCB)
42 electrical connections
46 motor controller
48A first output pin
48B first supply pin
48C second output pin
48D second supply pin
50 Liquid pump

We claim:

1. A cooling system for a computer system comprising:
a brushless motor, the brushless motor comprising
a rotor comprising a plurality of magnetic poles, the plurality of magnetic poles comprising at least a first magnetic pole and a second magnetic pole, wherein the rotor is arranged to rotate around a rotor axis;
a stator;
a first magnetic sensor;
a second magnetic sensor;
wherein the first magnetic sensor and the second magnetic sensor are arranged statically relative to the stator;
wherein the first magnetic pole is arranged at a first angle and the second magnetic pole is arranged at a second angle, wherein an angle is defined as an angle around the rotor axis of the rotor in a plane normal to the rotor axis;
wherein the first magnetic sensor and the second magnetic sensor are arranged with an angle difference corresponding to the angle difference between the first angle and the second angle;
wherein the first magnetic sensor and the second magnetic sensor are configured to combine signals output by the first magnetic sensor and the second magnetic sensor to form a combined signal, wherein the combined signal is used for control of the brushless motor; and
wherein the rotor and the stator rotate relative to each other.

2. The cooling system of claim 1, wherein the plurality of magnetic poles is evenly distributed angularly around the rotor axis.

3. The cooling system of claim 1, wherein the first and second magnetic poles are of opposite magnetization.

4. The cooling system of claim 1, wherein the first magnetic pole and the second magnetic pole are poles of a ring magnet, wherein the ring magnet is diametrically magnetized.

5. The cooling system of claim 1, wherein the first magnetic sensor and the second magnetic sensor are analogue magnetic sensors.

6. The cooling system of claim 1, further comprising a control unit comprising a processor, and wherein the magnetic sensors are electrically coupled to the control unit and are configured to cancel out a signal from a uniform magnetic field.

7. The cooling system of claim 1, wherein a radial distance from the first magnetic sensor and the second magnetic sensor to the rotor axis is equal to a radial distance from a center of each of the plurality of magnetic poles to the rotor axis.

8. A method for controlling a cooling system for a computer system comprising:
providing a brushless motor, the brushless motor further comprising a magnet having at least a first magnetic pole and a second magnetic pole, wherein the magnet is arranged to rotate with a rotor of the brushless motor;
providing a first magnetic sensor for recording a first signal;
providing a second magnetic sensor for recording a second signal;
combining the first signal and the second signal to form a combined signal; and
controlling the brushless motor based on the combined signal.

9. The method of claim 8, wherein combining the first signal and the second signal comprises averaging the first signal and the second signal, wherein an impact of a variance of the magnetic poles on control of the brushless motor is decreased.

10. The method of claim 9, wherein an external magnetic field is reduced by the first magnetic sensor recording the external magnetic field in an opposite direction of the second magnetic sensor to cause the averaging of the first signal and the second signal to reduce influence of a static magnetic field.

11. The method of claim 9, wherein an external magnetic field is reduced by the first magnetic sensor recording the external magnetic field in a same direction of the second magnetic sensor to cause the first signal to have an opposite sign of the second signal.

12. The method of claim 8, wherein the first magnetic sensor and the second magnetic sensor record nonlinear magnetic fields from the magnet and/or from currents of a stator to cause the combined signal to compensate for the nonlinearity.
